(19) United States
(12) Patent Application Publication
(10) Pub. No.: US 2024/0313796 A1
(43) Pub. Date: Sep. 19, 2024

(54) CHARGE DOMAIN APPROACH TO OVERSAMPLING CONVERTERS

(71) Applicant: DAVID SCHIE, Houston, TX (US)

(72) Inventor: DAVID SCHIE, Houston, TX (US)

(21) Appl. No.: 18/400,232

(22) Filed: Dec. 29, 2023

Related U.S. Application Data
(60) Provisional application No. 63/490,336, filed on Mar. 15, 2023.

(51) Int. Cl. H03M 1/12; H03M 3/00

(52) U.S. Cl. CPC H03M 1/1245; H03M 3/39

(57) ABSTRACT

A charge domain sigma delta analog to digital converter (ADC) is taught. A combiner is taught which acts as a delta operator and the same structure is also separately used as an adder in an NTF. The charge coupled combiner has a source of an input charge from a wired pair of diodes which creates a replica charge which cannot be destroyed. An output charge domain shift register comprised of memory nodes is provided. A second charge domain shift register and wired device is provided which is used with said combiner to implement an NTF. A quantizer is taught using a barrier whose height represents a discrete charge threshold. An NTF coupled to the quantizer provides charge which will either exceed or not exceed said threshold. A thyristor will actuate a subtract or add function at the delta combiner depending on the quantizer level to act as the DAC function of the ADC.

### RELATED APPLICATIONS

This patent application is related to U.S. Provisional Application No. 63/490,336 filed Mar. 15, 2023, entitled “A CHARGE DOMAIN APPROACH TO OVERSAMPLING CONVERTERS”, in the names of the present inventors and which is incorporated herein by reference in its entirety. The present patent application claims the benefit under 35 U.S.C. § 119(e) of the aforementioned provisional application.

### TECHNICAL FIELD

The present application in general relates to oversampling converters, and more specifically, to an oversampling converter using charge domain components.

### BACKGROUND

Oversampling converters sample and digitize analog signals. There are many implementations of oversampling converters. However, in general, the output of a quantizer is converted to an analog signal and subtracted from the input analog signal, after which the result is integrated and used to actuate the quantizer for the next subtraction. In certain domains such as image sensors, devices have been created which can collect, manipulate, and move charge effectively but heretofore have only been used in specific devices like image sensors. Oversampling converters have heretofore been built using transistors, however, here we teach the use of components more commonly associated with image processing (i.e., charge domain) to implement general oversampling converter functionality instead of using transistors. The benefits of this are that it can directly couple to devices such as pixels (pinned photodiodes), can achieve improved signal to noise ratios compared to transistor-based implementations, and can improve the performance and power required to perform the conversion task compared to transistor-based implementations.

### SUMMARY

In accordance with one embodiment, a charge coupled combiner is disclosed. The charge coupled combiner is provided a source of an input charge. An output memory node is provided. A subtract memory node is provided. A notch transfer gate is provided which consists of three elements: i) a barrier which can be raised or lowered; ii) a notch also capable of being raised or lowered whose potential is lower than the said barrier when lowered, and; iii) a fixed barrier which is not lowered. This notch transfer gate may use implants and a combined gate over the first and second elements to implement the potentials required for its functionality, or separate controlled gates may be used over each of the first and second elements of the notch transfer gate to control said functionality. In the combiner, a notch transfer gate is coupled between a source of the input charge and an output memory node. A second notch transfer gate is coupled between a subtract memory node and the output memory node. The notch level of each of the notch transfer gates may be programmed according to a notch depth to add or remove a programmable quantity of charge. For example, a two capacitor charge multiplier can be used to program the notch depth to set the amount of charge to be added or removed as further taught herein. A signal is coupled to one or the other of the two transfer gates to either add charge to or remove charge from the output memory node.

In accordance with one embodiment, an oversampling converter is disclosed. The oversampling converter has a source of an input charge. A combiner receives the input charge, and adds or removes charge from the input charge in conformance with a quantizer output signal. A noise transfer function implemented by one or more combiners, and one or more charge domain shift registers is provided and coupled to said first combiner. A quantizer is coupled to said noise transfer function output and generates the quantizer output signal which is coupled to said first combiner to decide whether to add or remove charge during the next cycle. A wired device and charge coupled shift register may be used within said H(z) to allow storage of the previous cycle charge value, or the input combiner can produce two or more copies of its output and shift them into the one or more charge domain shift registers of the H(z). More specifically, the sigma delta converter is implemented using charge domain components—a combiner, charge domain shift register, and charge domain quantizer and a high gain actuation device. The notch depth of the first combiner may be programmed by the two capacitor charge multiplier as further taught herein. The capacitor multiplier is used to set the combiner notch gate depth according to +Qref/2 or −Qref/2 such that it may be subtracted from the input charge. A discrete time delaying filter, such as a delaying integrator, is created by having the shift register and another combiner add the previous delaying filter output charge to the present cycle delta output of the first combiner (used as a subtractor). A quantizer is created by establishing a barrier whose height corresponds to a threshold. This could be established also with a two capacitor multiplier controlling a barrier height instead of a notch depth (by reversing the terminals). If the delaying filter output charge exceeds the barrier height, then a high gain actuator like a thyristor will actuate the gate of one of the transfer gates of the first combiner, otherwise it will actuate the other. This will either add charge to or subtract charge from the input charge during the next delta operation. To allow subtraction from the input charge without destroying it, a wired device may be used to create a replica or alternatively a charge domain shift register can produce multiple copies of the input value and provide it to the combiner with each cycle. A similar replication can be done from the output of the first combiner or within the shift register to have the previous cycle value available for the delaying filter functionality.

In accordance with one embodiment, a method to increase an accuracy of charge accumulating on an input of a single transistor multiplier (STM) MAC is disclosed. The idea is to use one or more sigma delta converters, one for each charge input, in conformance with the charge movement device magnitude and to compare the STM output with the input u(n). The input u(n) could be supplied as a pulse and the error the difference between the input pulse and the pulse created by the STM. Alternatively, the output of the STM could be used to set the notch depth in a notch transfer gate, which can be subtracted from a u(n) supplied as an input charge. For each charge input the oversampled digital output is stored in a CCSR. Once all of the inputs are calibrated in this way, the input charges an be coupled to the STM gate node.

In accordance with one embodiment, a method to introduce charge into a charge domain by utilizing a floating capacitor is disclosed. The method comprises: connecting the floating capacitor between the first and second control gates of a notch transfer gate to adjust the depth of a notch; and feeding the floating capacitor with a current source during one cycle; wherein the notch transfers a charge to a memory node (MN) during another cycle according to its notch depth. The charge introduced by the memory node (MN) therefore being proportional to the charge introduced by the current source.

In accordance with one embodiment, a method to control the depth of a notch in a notch transfer gate is disclosed. A two capacitor charge multiplier circuit is used in this case to control the notch depth and thus the charge to be transferred by a notch gate. The circuit has a pair of series capacitors, wherein the pair of series capacitors comprises a first capacitor and a second capacitor, the first capacitor having a first terminal, and a second terminal coupled to a first terminal of the second capacitor, both the first and second capacitors being floating capacitors. A first current source is coupled to the first terminal of the first capacitor, the first current source provides a charge input. A first switch is coupled to ground and the first terminal of the first capacitor. A second current source is coupled to the second terminal of the first capacitor and the first terminal of the second capacitor. A second switch is coupled to the second current source and to ground. A third current source is coupled to the second terminal of the second capacitor. A third switch is coupled to the third current source and to ground. A common source natural mosfet (Vth=0 to switch) acting as a comparator is provided and has a gate terminal coupled to the second terminal of the first capacitor and the first terminal of the second capacitor and a drain terminal coupled to an active load and to the actuator of the second and third current sources and a source terminal to coupled ground. The common source mosfet acts as a comparator around 0V in combination with the active load to cause the second and third current sources to provide charge if the output is below 0V. In reality, rather than relying on a natural mosfet with a trip point at 0V we would add an initial cycle where we close all three switches to discharge the capacitors, then release the 2^{nd} and third switches with the current source comparator actuating only the second current source (not third). This would load the comparator switch point negatively into the first capacitor in CDS fashion. With the trip point loaded we can then operate as if it were a natural mosfet. For this explanation we will continue with the Vth=0 analogy for simplicity. During a first cycle, a charge is added to the first capacitor using the first current source with the second switch closed and all other switches open. In a second cycle the first current source is turned off and the first switch is turned on. This will push the common source mosfet gate to a value below 0V which turns on the second and third current sources until the common source mosfet gate returns to 0V and stops the charging by turning off the second and third current sources. By controlling the ratio of the second to third current sources, the charge multiplicand can be programmed. Using all three switches the capacitors can be discharged. By coupling the terminal connecting the two capacitors to the first gate in a notch transfer gate and the second terminal of the second capacitor to the second gate of the notch transfer gate the two capacitor charge multiplier can be used to program the depth of the notch gate.

In accordance with one embodiment, a sigma delta converter is disclosed. The sigma delta converter uses a two capacitor charge multiplier and novel switching to implement analog to digital conversion oversampling functionality. A first capacitor, C1, second terminal, the summing node, is coupled to an output of a two level charge based quantizer and to a second switch to ground, SW2. The quantizer constitutes a quantizer comparator, latch, and current pulse generator to enable one of either adding or subtracting Qref/2 from the summing node based on a previous sigma delta cycle delaying filter output value. C1's first terminal is coupled to a switch to ground, SW1, and to one of either a first current source, Isrc1, or to a transconductor, GM1. The first capacitor, C1, holds the previous cycle delaying filter output, where the delaying filter allows the signal (STF) to pass and blocks the noise (NTF). An example would be a discrete delaying integrator. During a first cycle, to the output of the delaying filter charge from the previous sigma delta cycle already in Clis added the input charge by said Isrc1 with SW2 closed, or alternatively by GM1, responsive for example to a FD potential. During a second cycle SW2 is opened and SW1 closed. The pulse generator of the two level quantizer is then enabled and one of adds or subtracts a charge corresponding to +Qref/2 or −Qref2 depending on the value of the delayed integrator output from the previous sigma delta cycle (held by the latch). During a third cycle, a differential comparator or natural (around 0V) common source mosfet with active load acting as a comparator is enabled which turns on a current source, Isrc3, coupled to the second terminal of said second capacitor, C2, which will cancel the charge on said first capacitor, C1 (at which time said common source comparator input returns to 0V) charging through the series connected C1 and C2 which produces the delta and sigma operation and leaves the delaying filter output on C2. SW2 is then closed and one of either the voltage or charge on C2 is used by the quantizer comparator to latch the present cycle quantizer output value to use it as the quantizer result on the next sigma delta cycle. SW2 is then opened and SW3 closed and Isrc1 enabled to transfer the charge in C2 to C1 as the delaying integrator output for the next sigma delta cycle. The quantizer comparator output also represents the oversampled digital value which is stored for later filtering in a shift register. The above description suggested the use of a natural mosfet for simplicity of explanation, however, in reality the trip point of the natural mosfet still varies and therefore it is better to store the trip point of the common source comparator, whether it be natural or not, in C1 during an additional CDS cycle. To do this we introduce Isrc2. The CDS cycle occurs before any other operation and is not repeated during each sigma delta multicycle oversampling activity. In this case Isrc3 is disabled and the common source comparator with the active load, Iload, instead actuates Isrc2. Initially, SW3 is turned on as is SW2 and SW1 to discharge C1 and C2. SW2 and SW3 are then released and Isrc2 enabled. Isrc2 will charge the second terminal of C1 until it reaches the switch point of the common source mosfet. SW1 is then opened and the charge related to the switch point will stay on C1 to store the switch point offset for the duration of the multicycle sigma delta oversampling operation. Alternatively the common source comparator could be replaced by a differential comparator. If this CDS method of considering the trip point of the common source comparator is used, then the quantizer comparator must also consider the common source comparator's trip point when it selects the quantizer output. This is because C2 will have loaded this offset when the delaying Integrator output is stored in C2. This can be accomplished by using a series diode connected mosfet of the same geometry as the common source mosfet in series with the reference level of the quantizer and considering appropriate matching procedures for the mosfets.

### BRIEF DESCRIPTION OF THE DRAWINGS

The present application is further detailed with respect to the following drawings. These figures are not intended to limit the scope of the present invention but rather illustrate certain attributes thereof.

FIG. 1 is a diagram illustrating three recognized domains: i) the charge domain of pinned photodiodes, charge domain shift registers, floating diffusions, memory nodes, notch gates, etc.; ii) the analog domain of transistor-based circuits using their V-I characteristics and iii) the digital domains using transistors as switches in accordance with one aspect of the present application;

FIG. 2 is an exemplary shift register using flip flops in accordance with one aspect of the present invention;

FIG. 3 is an exemplary flip flop using transistors in the domain in accordance with one aspect of the present invention;

FIG. 4A is a cross section of an exemplary shift register in the charge domain in accordance with one aspect of the present application;

FIG. 4B is an exemplary charge transfer diagram for the shift register in the charge domain of FIG. 4A in accordance with one aspect of the present application;

FIG. 5 is a top view of an exemplary two-dimensional shift register in the charge domain in accordance with one aspect of the present application;

FIG. 6 is a block diagram of an exemplary serial in serial out (SISO) wired shift register, also the “wired device” referred to herein for replicating a charge value, in accordance with one aspect of the present application;

FIG. 7 illustrates the block diagram of an exemplary first order sigma delta oversampling converter in accordance with one aspect of the present application;

FIG. 8A shows a second block diagram associated with a sigma delta converter including a H(z) filter, a quantizer, a DAC, two summers and feedback in accordance with one aspect of the present application;

FIG. 8B shows the block diagram from FIG. 8A where the quantizer is represented as the combination of an input signal and a quantization error;

FIG. 9 shows a 2nd order NTF sigma delta oversampling feedback structure in accordance with one aspect of the present application;

FIG. 10A illustrates a combiner that can accept charge from multiple directions (in or out of the page) and add to it or remove from it from a memory node in the center (MN) using two separate notch gates in accordance with one aspect of the present application;

FIG. 10B illustrates exemplary charge transfer diagrams of the combiner of FIG. 10A in accordance with one aspect of the present application;

FIG. 11 illustrates an exemplary quantizer that works by accepting an input charge, where the input charge is smaller or larger than a built-in barrier height and therefore spills charge to the output memory node or does not spill charge into the output memory node in accordance with one aspect of the present application;

FIG. 12 illustrates an exemplary CCSR input sigma delta ADC in accordance with one aspect of the present application;

FIG. 13 is an exemplary wired device input sigma delta ADC in accordance with one aspect of the present application;

FIG. 14A-14C shows an exemplary method to set a charge in a CCSR instead of using a combiner in accordance with one aspect of the present application;

FIG. 15 shows an exemplary technology computer-aided design (TCAD) simulation of a CCSR illustrating that it can operate at 1 GHz with 14 nm features sizes in accordance with one aspect of the present application;

FIG. 16 shows an exemplary sigma delta MAC (multiply-accumulate circuit) in accordance with one aspect of the present application;

FIG. 17 shows an exemplary MIM capacitor over charge domain devices and circuitry in accordance with one aspect of the present application;

FIG. 18 shows an exemplary VIA capacitor in accordance with one aspect of the present application;

FIG. 19 shows an exemplary circuit to introduce a correlated charge into a charge domain structure in accordance with one aspect of the present application;

FIG. 20 shows an exemplary hybrid sigma delta circuit in accordance with one aspect of the present application;

FIG. 21 shows an exemplary two capacitor charge multiplier in accordance with one aspect of the present application.

### DESCRIPTION OF THE APPLICATION

The description set forth below in connection with the appended drawings is intended as a description of presently preferred embodiments of the disclosure and is not intended to represent the only forms in which the present disclosure can be constructed and/or utilized. The description sets forth the functions and the sequence of steps for constructing and operating the disclosure in connection with the illustrated embodiments. It is to be understood, however, that the same or equivalent functions and sequences can be accomplished by different embodiments that are also intended to be encompassed within the spirit and scope of this disclosure.

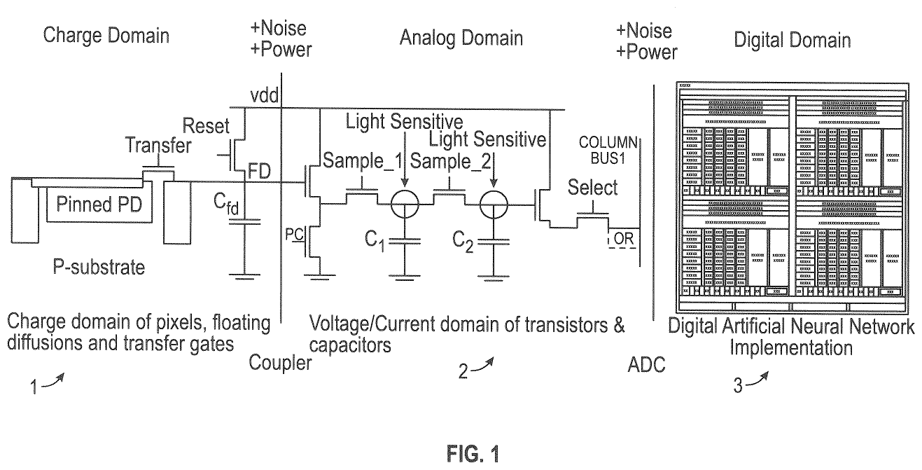

In electrical circuits, there may be three recognized domains. Referring to FIG. 1, the three recognized domains may be shown with a boundary positioned between each domain. The three recognized domains may be: charge domain 1, analog domain 2, and digital domain 3. In accordance with one embodiment, the charge domain 1 may be defined as the world of pixels and components such as charge coupled shift registers (CCSR), pinned photodiodes (PPD), floating diffusions, and transfer gates which transfer charge using fill and spill techniques. The analog domain 2 may be defined as the domain of transistors used based on their current and voltage characteristics or domain 3 where transistors are used as a switch in digital gates to produce digital functionality.

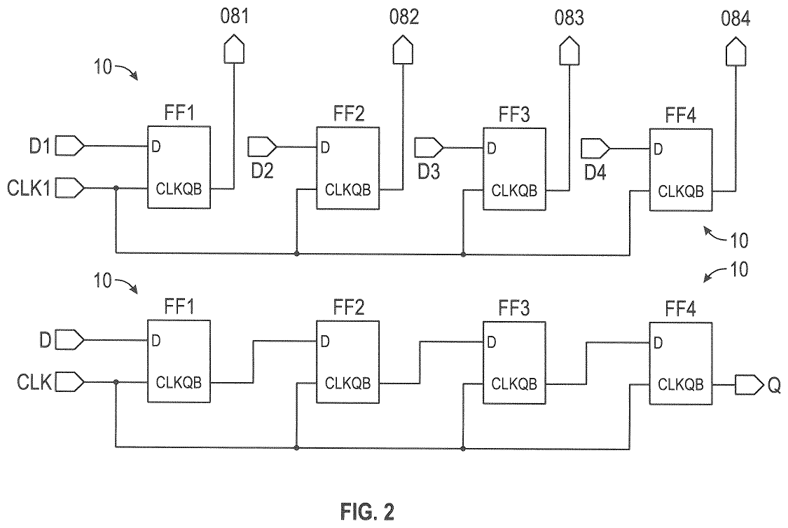

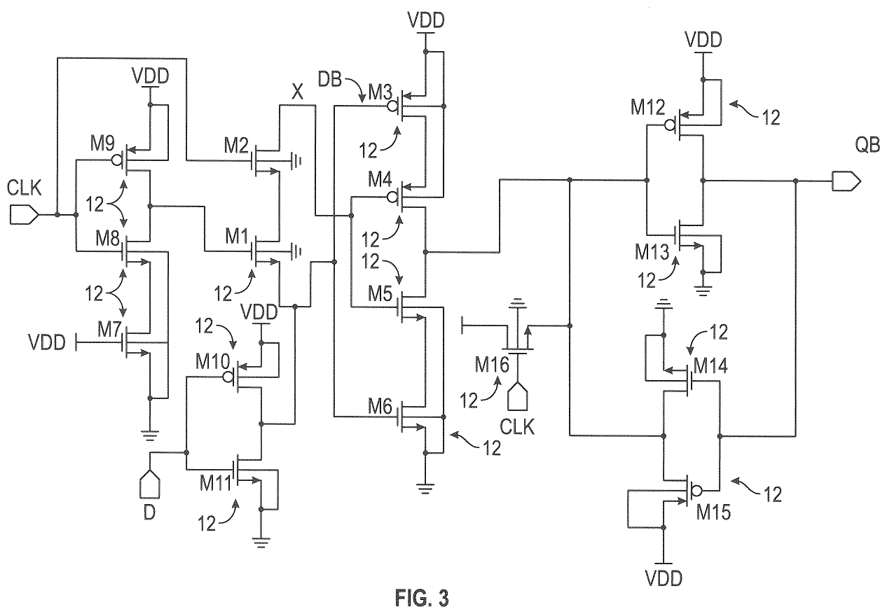

Referring to FIGS. 2 and 3, examples of digital implementations are shown. FIG. 2 shows an overview of a digital shift register implementation using flip flops 10. FIG. 3 shows the transistor detail for the digital implementation of the flip flops 10 using transistors 12.

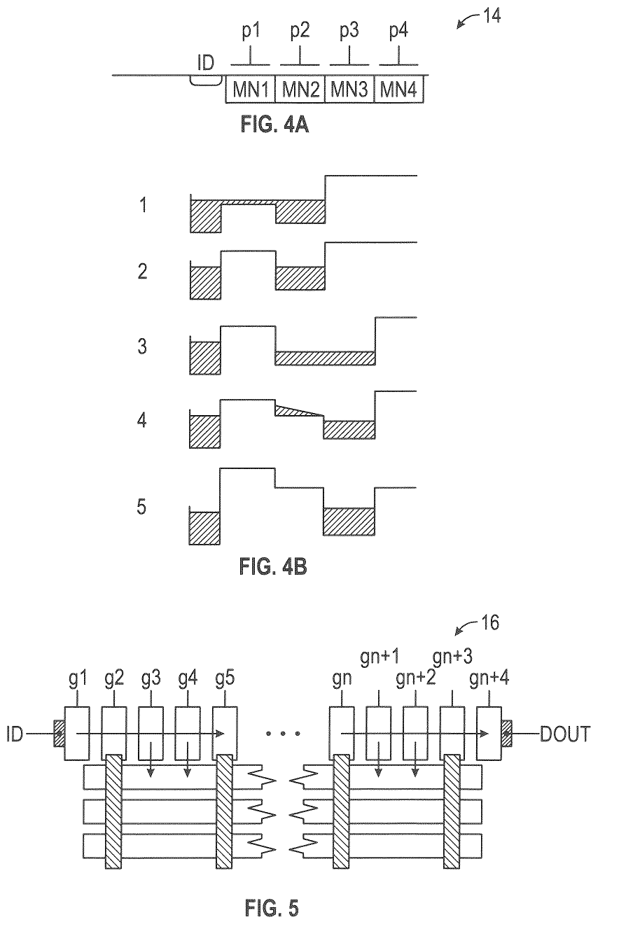

Referring to FIG. 4A, a shift register 14 in the charge domain may be shown. The shift register 14 may perform in a similar function to FIG. 2, however, it is done in the charge domain. It may be possible to replicate many analog domain functionalities, including digital gates, amplifiers, integrators, quantizers, combiners, and subtractors in the charge domain. The advantage of doing so may include, but not be limited to: lower noise, faster execution, and the ability to couple directly to the charge collected from charge domain devices such as pixels or MEMs devices which produce charge data (e.g., MEMs microphones, positioners, etc.).

Referring to FIG. 4A-4B, operation of the shift register 14 in the charge domain may be described. In the present embodiment, the shift register 14 may have four gates p1-p4 and four memory nodes, MN1-MN4, with a respective memory node located under a corresponding gates. In this case an input diode (ID) provides the input charge.

In a first cycle, if one lowers the p2 potential and the p1 potential (in the silicon under the gates), then one can share charge with the MN2 of p2. If one then raises p1 then p2 can be cut off from the ID and will contain the charge level of the ID. In step 3, one can lower p3 while p2 remains lowered causing the charge to be shared between MN2 and MN3. If one then lifts p2, the charge in MN2 under p2 will spill into MN3 under p3. Thus, one has the charge shifted from MN2 under p2 to MN3 under p3 illustrating the charge coupled shift register operation.

The shift register 14 in FIG. 4 may be extended into a multi-dimensional shift register 16 as may be shown in FIG. 5 looking down from the top at the control gates. In the embodiment, the charge may be moved in multiple directions. In accordance with one embodiment, one can fill the shift register 16 horizontally, and then parallel shift that entire shift register vertically (downwards). In other words, in the shift register 16, one may fill a column and then that column may shift its contents into parallel columns. This may produce a local charge memory. By using a buried charge-coupled device (CCD) structure it may be possible to move charge with a very high charge transfer efficiency (CTE)—i.e., without losing many electrons. In FIG. 5, since it may be shown that the charge may be moved in multiple directions, it creates a two-dimensional charge-coupled shift register (CCSR) which may contain a lot of MNs (i.e., becomes a charge domain memory).

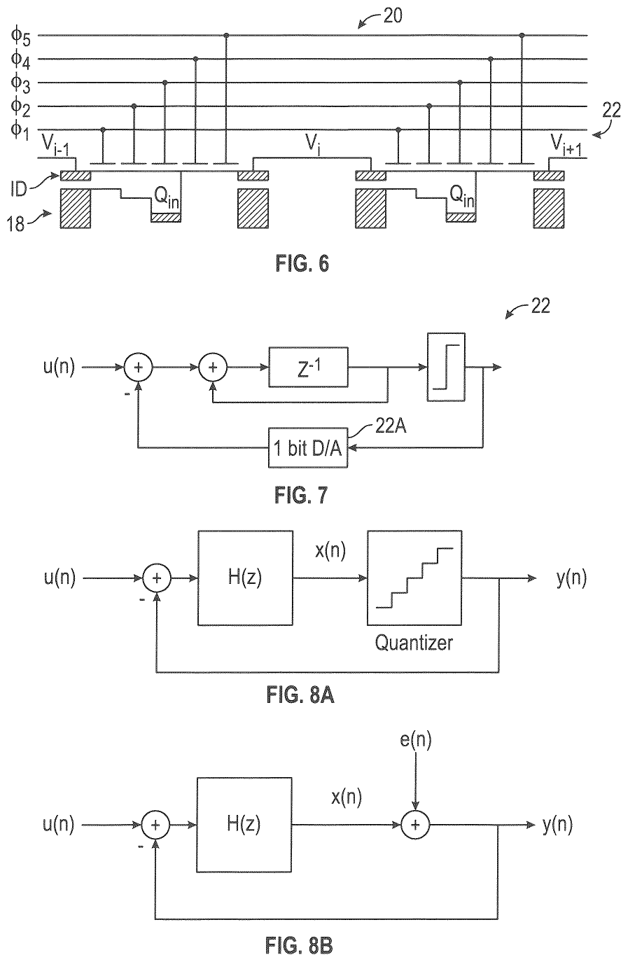

The shift register 16 in FIG. 5, as well as other charge domain circuits may have difficulty coupling over distances and to voltage mode devices due to their reliance on a continuous channel. To overcome this difficulty, it may be possible to utilize a wired device as shown in FIG. 6. In the embodiment shown in FIG. 6, a serial in serial out (SISO) wired shift register 18 may be shown.

In the shift register 18, a charge under a specific gate pn (diode) may be transferred to another location by wires which will replicate the charge under the gate pn (diode) and act as an input diode (ID) for downstream devices. The benefit of this structure is that one can move charge into a first of two diodes whose terminals are connected to together and the charge under the second diode will match and represent a copy which can then we used as to charge downstream MNs. In this way an input MN may be coupled to said first diode and its output may be spilled into a downstream MN coupled to said second diode. In this way we have a source of input charge that is not destroyed when used for example as the input to a charge domain sigma delta converter.

In FIG. 6, the shift register 18 may use a wired devices 20 to allow the copying of charge information from a different MN and then jumping by using the wired device 20 from one MN to another. In this case, if one can shift charge into the final MN using the wired device 20, then it may create exactly the same replica charge on the MN to which it is coupled. The fully charged MN under the wired device 20 is understood to have been the result of a previous transfer. These wired devices 20 allow us to create an ID of known charge for re-use such as the u(n) in a sigma delta converter, it may also allow one to jumper with metal the output of a charge domain circuit such that it may be coupled as an ID to one or more other charge domain circuits in another part of the silicon.

Referring to FIGS. 7 and 8, a first order sigma delta structure 22 may be shown. The loop transfer function may be defined as Y(z)=STF(z)U(z)+NTF(z)*E(z), where STF is the signal transfer function and NTF is the noise transfer function. STF(z)=Y(z)/U(z)=H(z)/(1+H(z)) and Ntf(z)=Y(z)/E(z)=1/(1+H(z)). One may want to transfer the signal and filter the quantization error using a delaing filter 24 (!!! this is not labelled on the diagram !!!). The sigma delta structure 22 may take an input and represent it accurately by a number of quantizer output values (oversampled) which can be averaged. For example, it could be represented by a succession of +Qref and −Qref pulses. If Qref's value is defined then a digital vector can be used to store the number of +Qrefs and −Qrefs according to the digital bit pattern (1 being +Qref and 0 being −Qref). This way an oversampled vector can stored which can recreate the analog value by averaging the appropriate number of mixed +Qref and −Qref inputs. The power of the implementation comes from converting quantized output to an analog value (DAC) which may be subtracted from the original input value to create an error which is input to a high gain NTFin an error feedback scheme.

In FIG. 7, one may use a 1 bit quantizer 22A so the charge associated with the quantizer may simply be subtracted or added to the input as a fixed charge. This quantization error can be high pass filtered by putting a zero at dc (z=1). In the loop, one may implement a filter H(z)=1/(z−1) or a delayed integrator. This is implemented by delaying the output of the input less the output DAC value by a cycle and adding it to the present value.

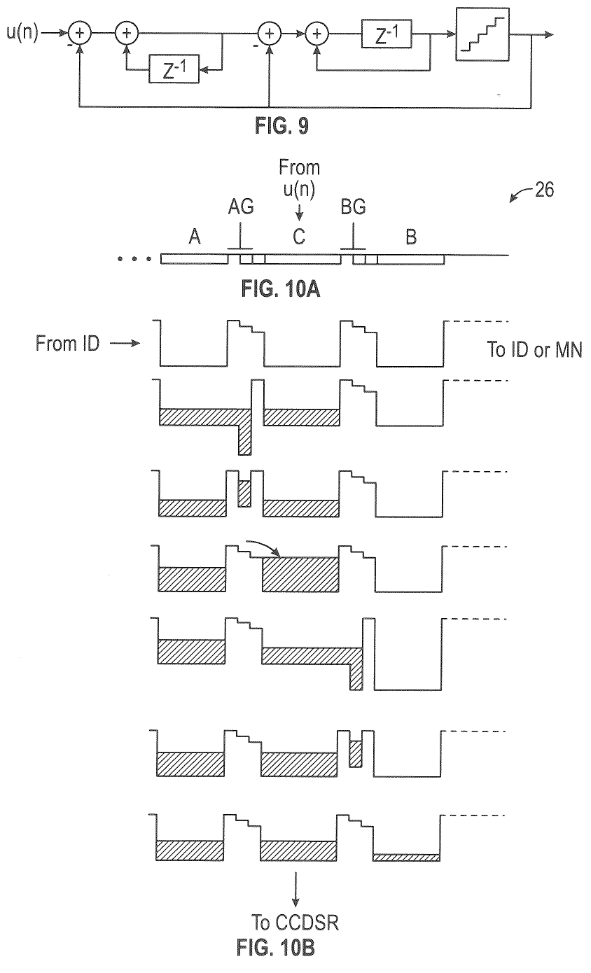

Referring to FIG. 9, a 2nd order NTF sigma delta oversampling feedback structure 24 may be shown. The block diagram and detail are shown in FIGS. 8A and 8B. The 2nd order NTF sigma delta oversampling feedback structure 24 shows an improved implementation with a higher order NTF implemented by cascading a second delaying integrator. There may be many schemes for improving the NTF and STF performance with all sorts of different filters, and parallel schemes like MESH, etc. All of these schemes may be implemented using the means taught herein. Higher order quantizers can be implemented by utilizing a quantizer structure with multiple barriers between MNs and adjusting different Q charge values with the activated high gain device coupled to each MN such as a thyristor responsive to the bins receiving charge as the overall charge spills across the different barriers. Alternatively, a combiner and charge domain digital gates implemented using combiners, along with barriers and notches or a hybrid structure with transistor based gates may be used.

Referring to FIG. 10A-10B, operation of a combiner 26 may be disclosed. The combiner 26 can add or subtract charge from multiple input paths. In accordance with an embodiment, the combiner 26 could accept a charge in a normal charge coupled shift register fashion from an adjacent MN and then add charge or remove charge in other directions (i.e., from other adjacent MNs) such as the horizontal directions or into the page in the diagram. To help control the transfer of charge, the combiner 26 may be built with notch transfer gates containing extra implants such as a spacer in the first element lowerable barrier, an n+ in the second element (notch), and p+ implant in the third element (fixed barrier), as shown in FIG. 10. Alternatively, the gate may be split such that the first element and the notch are each controlled by their own gate. Note that it is not necessary in this case to have then n+ implant underneath it but it can also be created with the n+ present. By separating the gates and using the two capacitor charge multiplier the delta between the barrier for lowering and the notch may be programmed as taught herein. In accordance with one embodiment, one can accept charge from multiple directions and add to it or remove from it from a MN either using conventional CCSR techniques or by creating a small notch which may transfer smaller quantities of charge over one or more cycles to better control the magnitude of charge transferred. Techniques may be taught which further allows the control of the height of the notch.

In this case, if one assumes charge resides to the left of the barriers, then when the left transfer gate is high the charge is blocked. If the transfer gate lowers the barrier, then we see a situation as shown in the 2nd level in FIG. 10B where the first element is lowered to the level of the input MN and the notch whose potential is below the level of the input MN fills with charge. If one raises the barrier and the notch at the same time, one may end up with a notch containing charge and charge stored in that notch. If one further increase the shared gate voltage then that notch charge will spill into the adjacent MN as shown in the third line of FIG. 10. If one has a similar construct to the right of the central MN then one can similarly transfer a notch charge out of the MN charge storage well. In this way one can add or remove charge as in FIG. 10B. By controlling the notch, a known charge may be transferred in one cycle or over multiple cycles very accurately.

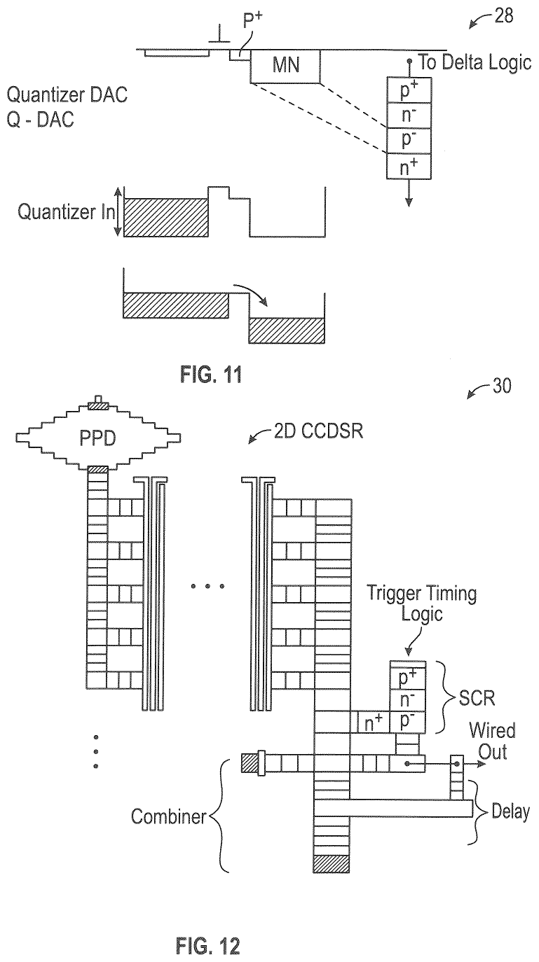

To implement an oversampling converter, one may need a quantizer. FIG. 11 illustrates a quantizer 28 that works by accepting an input charge, where the input charge is smaller or larger than a built-in barrier height. If less than the barrier, a high gain or positive feedback device coupled to the output MN will not trigger. If on the other hand the charge exceeds the barrier height then the charge spills over the barrier, then a high gain device such as a silicon controlled rectifier (SCR) may fire.

In accordance with one embodiment, the quantizer 28 maintains a barrier at a 50% of Q level (where the barrier height is selected according to 50% of the Q value for the quantizer decision). One may also introduce a high gain structure, in this case a thyristor or SCR where the trigger is actuated if charge spills over the 50% barrier. If the charge coming into the left side of the quantizer 28 in FIG. 11 is less than 50%, then no charge will spillover and the SCR will not trigger. If the charge is over 50%, then the charge will fire the SCR. The SCR output can be coupled to a circuit which actuates the notch transfer gate which removes charge with the input combiner each cycle if the thyristor is not triggered or actuates the notch transfer gate which adds charge each cycle if the thyristor is triggered. If the input were u(n) and the quantizer were to add or subtract a selected Qref/2 then one would have a quantizer and DAC operation per FIGS. 7 and 8 since it is a single bit quantizer.

The quantizer 28 may be part of a charge domain oversampling (sigma delta) converter. In one case the input information may come from a PPD, but it may just as easily come from an input diode (ID), a charge coupled MN or a wired device MN replica. In FIG. 12, one may utilize a charge coupled shift register to make enough copies of the input to meet one's oversampling requirement by having the previous cycle value available for the delaying integrator even as the copy is destroyed by the quantizer. As an alternative, one may assume that the integration and fill time for an input CCSR may be very short compared to the physical change in light that the PPD will see during the multiple integrations such that the samples are the same.

FIG. 12 illustrates a first order sigma delta converter 30 where a PPD input feeds a 2D CCSR 20 memory to create multiple input samples (u(n)), which in turn feeds a combiner (the delta part of sigma delta). A second combiner is fed with the first combiner delta output and to another CCSR which stores the previous output of the second combiner which is further fed to the second combiner to implement the delaying filter (the sigma part of sigma delta, in this case a delaying integrator). The output of the delaying filter is coupled to the quantizer whose output can be coupled to an SCR as described in FIG. 11 and further used to set the input combiner (delta function) direction (add or subtract charge).

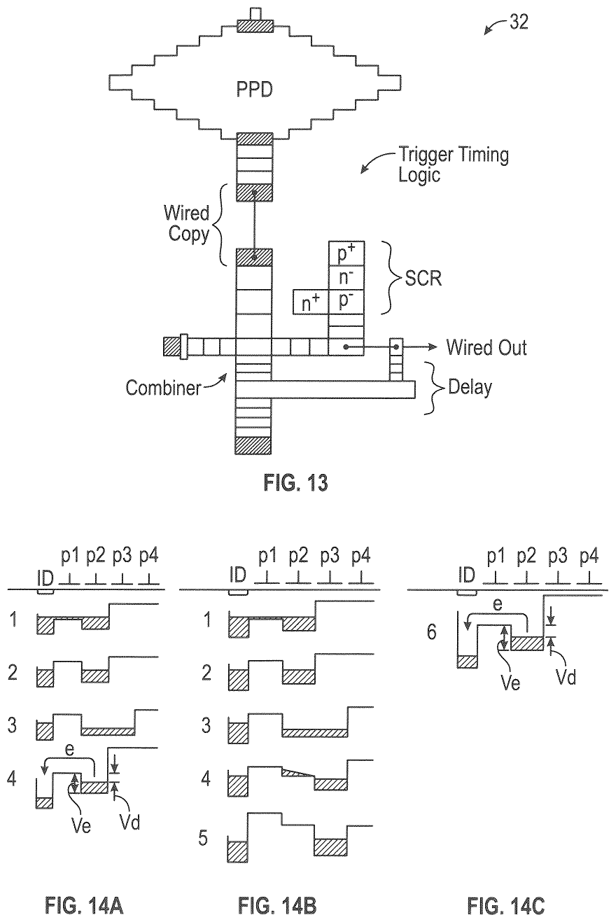

FIG. 13 illustrates a first order sigma delta converter 32 where a PPD input feeds a wired device used to create a replica which may be used as the input for the multicycle oversampling (where we need multiple copies of the input charge from which to subtract the quantizer/DAC output).

In FIG. 13, rather than copy the input multiple times, one may copy it once using a wired replica device as illustrated in FIG. 6. Using a wired device, one may simply have to fill the MN below the first wire with the PPD value, and then the connected wired MN will become an ID to the remaining CCSR or the CCSR can be removed altogether. If we were to directly couple the input charge without a wired device as a replicator or a CCSR to make multiple copies to provide to the delta combiner then the input charge would be destroyed on the first cycle when it was accepted by the first combiner and we would not be able to cover sample thereafter.

In FIGS. 12 and 13, the input is coupled to either a CCSR to make multiple copies of the input charge or to a wired device to make a replica of the input charge. Now the combiner subtracts the quantizer value (Qref/2 or −Qref/2) depending on the quantizer decision, and to that number adds the previously delayed value from the delaying filter output charge. This is done using the techniques for the combiner described above and the subtract followed by add could be done in one or more small cycles as long as the overall delay associated with z\hat{ }−1 represents the appropriate period associated with the H(z) filter. It is better to do it in one cycle. A CCSR may then be used to delay the delaying filter output result, using for example a wired device to make a replica copy of the delaying filter output, so that it can be wrapped around to the combiner for the next cycle. A wired replica may be coupled to the MN so as to make a copy of it and have it available for use next cycle by the delaying filter or a CCSR can be used. A circuit coupled to the quantizer output may be used as the output value and the value stored as our digital representation. In this diagram the detail of replicating the delaying filter output for forwarding to either the second combiner or the quantizer is not shown to keep the diagram simple.

One of the challenges in the charge domain is to introduce a charge from a source other than a light collecting source such as a PPD. FIG. 14A-14C illustrates a technique which may be used to set the charge in a CCSR instead of the combiner. In this case it relies upon the leakage through a barrier calibrated with time. In FIG. 14A-14C, the method relies upon the reverse leakage across a barrier, where electron flow rate across the barrier can be calculated and therefore the remaining charge becomes time dependent. A DAC can be used and calibrated to provide precise charge levels and this charge could further be used by a two capacitor charge multiplier as its base unit for creating notch or barrier levels. Alternatively, calibration can be achieved by creating notches which are applied to barriers coupled to subsequent MNs with the two capacitor charge multiplier and triggering an SCR on the output once a charge exceeds the barrier as the notch depth is increased. This will correlate the notch charge against barrier heights.

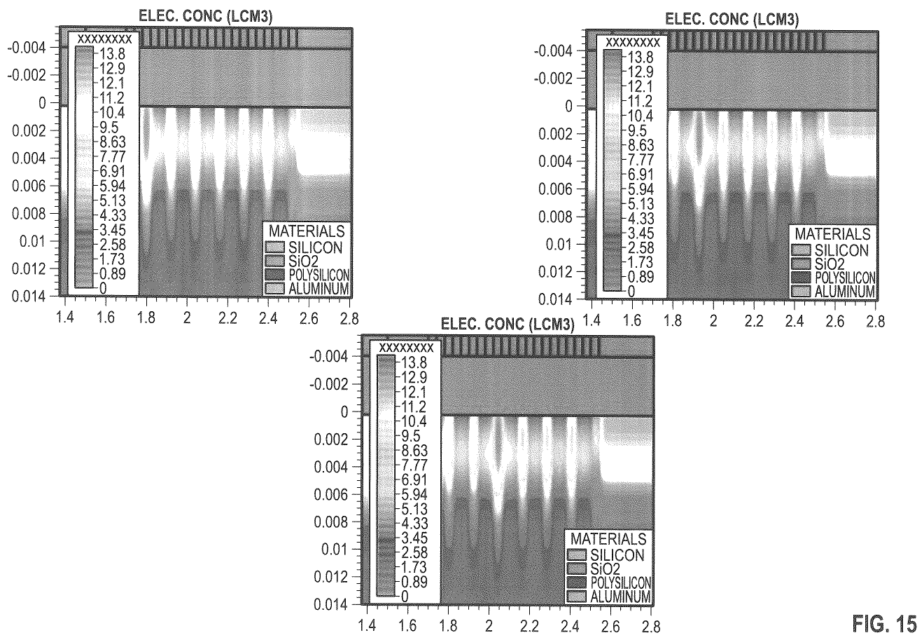

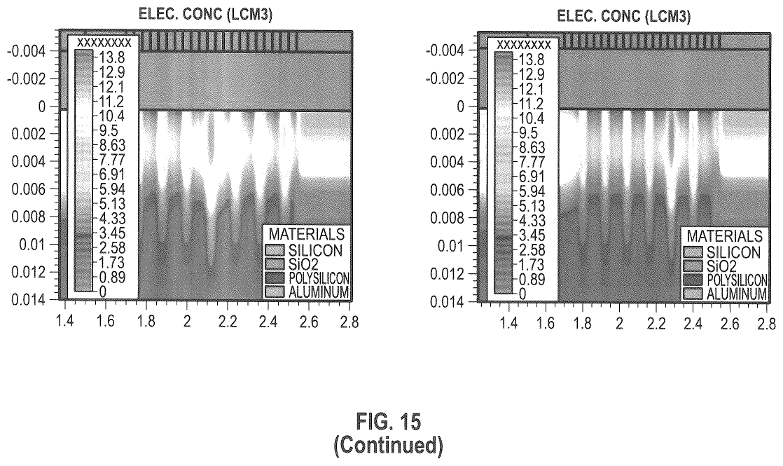

FIG. 15 shows a technology computer-aided design (TCAD) simulation to develop and optimize semiconductor process technologies and devices. The TCAD simulation is of a CCSR illustrating that it can operate at 1 GHz with 14 nm features sizes.

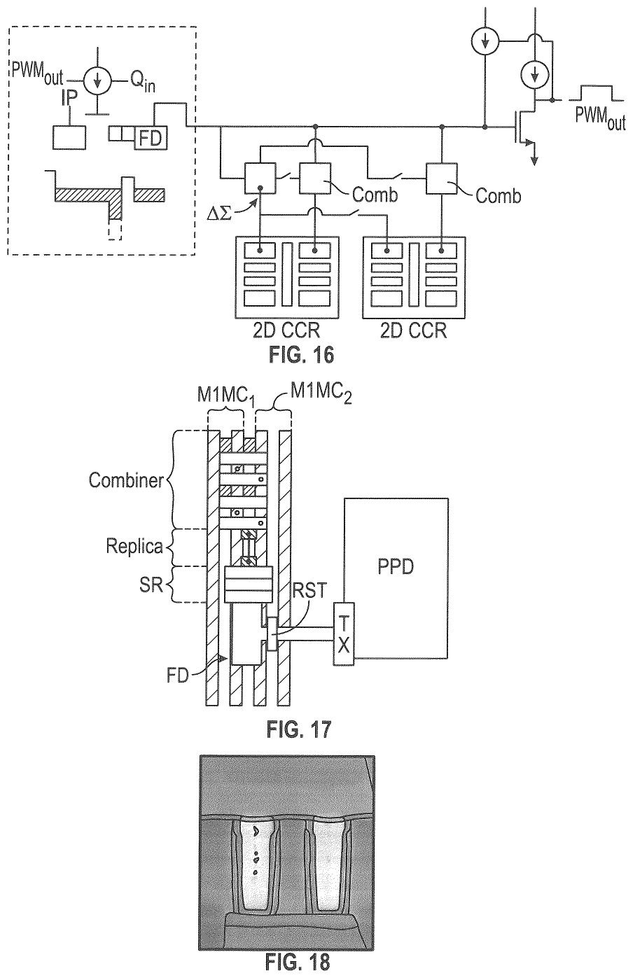

One may introduce charge using a fixed notch transfer gate as shown in FIG. 16 by changing the polarity of the current source to pump the gate voltage according to a PWM signal phi_in, or one may split the gate between the first and second elements of the notch gate and previously described. The depth of the notch may be adjusted by using the two capacitor charge multiplier described previously so that the correlation factor between the notch height and the charge that is transferred each cycle can be set. Charge may be transferred in a single cycle or over multiple cycles. The external capacitor can be fabricated as a MIM cap or a VIA cap above the circuitry, especially in back side illumination (BSI) processes, and as such does not need to take up silicon area.

FIG. 16 shows a means by which to increase the accuracy of a MAC utilizing multiple charge domain sigma delta converters at each input (such as the sigma delta described in FIG. 12) each storing the sigma delta digital oversampled outputs in its own 2D shift register. For each sigma delta oversampling cycle the input pulse is repeated and compared with the STM output pulse. The difference is converted to charge using one of the techniques taught herein and stored in a memory node and used as the delta output/input to the NTF. To be more specific we produce a digital oversampled vector in conformance with a sigma delta converter that compares the input pulse for a given weight input to the STM to the output pulse of the STM being calibrated. By working through each input one by one the magnitude variations of the weights can be isolated and we can store the oversampled result on 2D shift registers (vectors) associated with each input. Once we have an oversampled vector for each STM weight input we can introduce the oversampled input during a summing phase, simultaneously or in any combination, with the appropriate current magnitudes gated by the digital oversampled vector information to improve the accuracy of each of the inputs vs. its original input.

FIG. 16 also introduces the use of charge domain techniques to close the loop using sigma delta feedback between an STM MAC and its inputs. In this case we use the single transistor multiplier as disclosed in U.S. Pat. Nos. 11,087,099 and 11,755,850 both assigned to the same assignee as the present application and which are incorporated herein by reference. The STM MAC relies on a common source mosfet acting as a comparator in cooperation with an active load whose gates is also used to sum charge. In the single transistor multiplier (STM) current sources whose magnitudes represent a weight value, are coupled to the gate and are actuated by PWM pulses representing input values. The actuation time multiplied by the current magnitude adds or subtracts charge to the gate during a first cycle. In a second cycle a current source brings the gate back to its threshold to produce a PWM output proportional to the sum of charge.

As an alternative method to create the delta error, we can use either a two capacitor multiplier with a current source gated by the output of the STM or charge the control the gate of a notch gate to introduce charge to the MN output node of a combiner by setting the notch size, one can translate from pulse width to a charge for use by the sigma delta which can accept that value through a wired device to add or subtract the quantizer result. To replicate the sigma delta output charges later, one may use a wired device or store those charges in a 2D CCSR. Once all the sigma delta parallel inputs have closed the loop with the MAC pulse output independently, one can allow all the 2D CCSRs and any simple current source gated inputs to all sum into the gate with improved accuracy on the sigma delta input channels during an input charge phase. Thereafter, in a second phase, a proportional current source will return the gate to its threshold to provide an accurate pulse output representative of the overall summed charge. It should be noted that the introduction or removal of current to the summing gate node of the STM could be done using a combiner and MN coupled to said summing gate, using fixed frequency periods actuating said transfer gates where the MN is further coupled to the STM summing gate. More specifically, we can create charge movement devices by setting the notch gate depth of a notch transfer gate and then controlling the frequency of transfer of charge by that transfer gate to an MN and further coupling that MN output to the STM summing node.

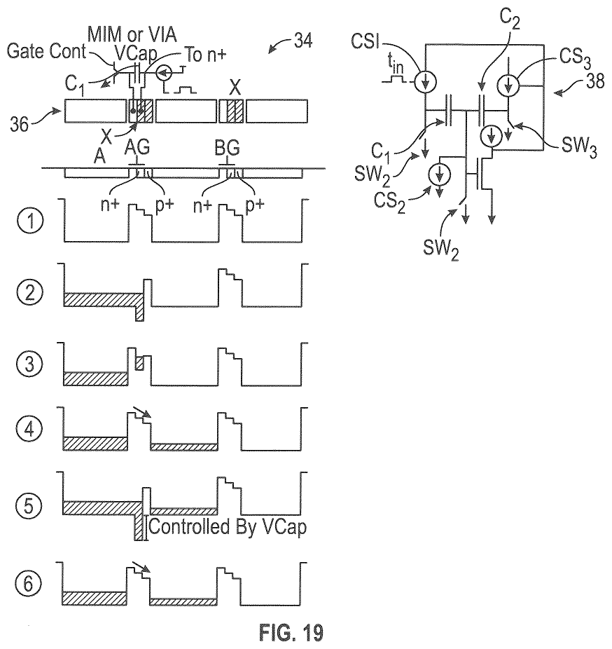

FIG. 19 illustrates a mechanism by which the notch depth of a notch transfer gate can be set by a current source and a capacitor connected between the first barrier capable of being lowered terminal of the notch gate and the notch terminal (usually but not always with an n+ implant under it). Once the notch is set, we have correlated a fixed charge that can be used as a base unit in a multiple cycle pump action to move a proportional amount of charge into the central MN node. The method may utilize a hybrid structure 34 to introduce a correlated charge into a charge domain structure 36. To better control the ratio charge from a unit charge to a multiplicand of that unit charge the two capacitor charge multiplier may be used 38 where C₂ takes the place of C1 described previously. The two capacitor charge gain circuit was first disclosed in U.S. Pat. No. 9,692,376B2 “Controlled switched capacitor coefficients.”

The hybrid structure 34 has a pair of series connected capacitors Cₛ, wherein the pair of capacitors comprises a first capacitor C₁ and a second capacitor C₂. The first capacitor C₁ has a first terminal and a second terminal. The second terminal of the first capacitor C₁ is coupled to a first terminal of the second capacitor C₂.

A first current source CS₁ may be coupled to the first terminal of the first capacitor C₁ the first current source provides a charge input. A first switch SW₁ may be coupled to ground and the first terminal of the first capacitor C₁.

A second current source CS₂ may be coupled to the second terminal of the first capacitor C₁ and the first terminal of the second capacitor C₂ and ground. A second switch SW₂ may be coupled from the second terminal of C₁ and first terminal of C₂ and to ground. A third current source CS₃ may be coupled to the second terminal of the second capacitor C₂. A third switch SW₃ may be coupled to the third current source CS₃ and to ground;

A mosfet with active load is used as a comparator around ground (natural device) to actuate CS₂ and CS₃ when its gate is below ground and SW₁ closed. To understand how one can control the charge ratio between the capacitors using only current ratios, consider the following. First let's load a charge by turning on SW₂ and CS₁ for a duration of time corresponding to the charge value we want to load. Thereafter, we turn off SW₂ and turn on SW₁. This will push the node between the capacitors negative and turn on CS₂ and CS₃. CS₃ charges both capacitors discharging the charge previously loaded onto C₁ at which point the voltage on the gate of the mosfet will return to zero and CS₂ and CS₃ will turn off. Noting that CS₂ reduces the current available to charge C₁ but that C₂ receives the full CS₃ we see that the ratio of currents controls the charge on C₂. Note that C₂ is coupled to the terminals of the notch transfer gate such that if we define a minimum input charge with it then we can control multiplicands of input charge thereafter to scale the notch depth and thereby the charge ratio transferred in the charge domain structure.

In FIGS. 17 and 18 it is shown that one can fabricate the capacitors of the two capacitor charge multiplier or other capacitors over the active areas using MIM capacitors or VIA capacitors so that they do not increase the die size despite the charge domain/analog hybrid implementation. It should also be noted that two capacitor charge multiplier can also sum additional charge each cycle even as multiplicands are changed according to the current ratio if the second capacitor charge is not cleared each cycle and only the first capacitor charge is cleared each cycle, for example by only shorting SW1 and SW2 to ground between cycles instead of all three switches.

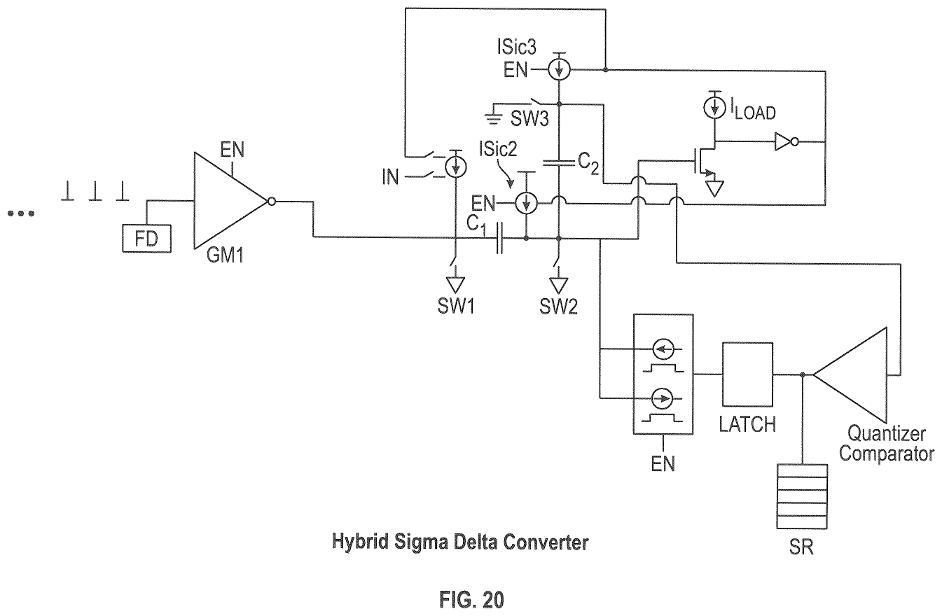

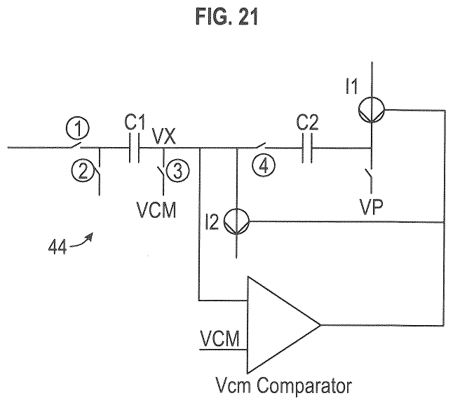

Referring to FIG. 20, a hybrid sigma delta device 40 that utilizes the common source comparator and the two capacitor charge multiplier is shown.

In FIG. 21, the two capacitor charge multiplier circuit from U.S. Pat. No. 9,692,376B2 is shown.

The foregoing description is illustrative of particular embodiments of the invention but is not meant to be a limitation upon the practice thereof. The following claims, including all equivalents thereof, are intended to define the scope of the invention.

What is claimed is:

1. A charge coupled combiner comprising:
a source of an input charge;
a first memory node;
a second memory node;
a first transfer gate coupled between the source of the input charge and the first memory node, and a second transfer gate coupled between the first memory node and the second memory node wherein an actuation of the first transfer gate adds charge to the first memory node and actuation of the second transfer gate removes charge from the first memory node;
signals coupled to the first transfer gate and the second transfer gate to actuate the first transfer gate and the second transfer gate.

2. The charge coupled combiner of claim 1, wherein the first transfer gate and the second transfer gate are notch transfer gates.

3. The charge coupled combiner of claim 2, wherein the second notch transfer gate comprises a combination of at least one of implants or spacers formed under the gate portion of the transfer gate to form a barrier capable of being raised or lowered and a charge notch capable of being raised or lowered, and a fixed barrier portion of the transfer gate not residing under the gate portion of the transfer gate.

4. An oversampling converter comprising:
a source of an input charge;
a combiner receiving the input charge, and adding or removing charge from the input charge in conformance with a quantizer output signal;
a delaying filter; and
a quantizer coupled to a delaying filter output and generating the quantizer output signal.

5. An oversampling converter of claim 4, wherein the filter includes a charge coupled shift register;

6. An oversampling converter of claim 5, comprising a combiner coupled to the shift register.

7. The oversampling converter of claim 4, comprising a charge coupled shift register making multiple copies of the charge input for use during oversampling.

8. The oversampling converter of claim 4, comprising a wired device making an input diode replica copy of the charge input for use during oversampling.

9. The oversampling converter of claim 4, wherein the quantizer comprises:
a first memory node (MN);
a second MN;
a fixed barrier between the first MN and the second MN whose height is set in conformance with a charge threshold; and
one of a high gain or positive feedback device coupled to the second MN to output the state of the quantizer;
wherein when the quantizer accepts the input charge, the input charge will one of fail to spill over the fixed barrier or spill over the barrier into the second MN.

10. The oversampling converter of claim 9, wherein the barrier is formed by using at least one of implants or spacers at the surface.

11. The oversampling converter of claim 9, wherein the one of the high gain or positive feedback device is a thyristor.

12. The oversampling converter of claim 9, wherein a p implant is used to collect stray carriers coupling from the substrate to the MNs.

13. A method to increase an accuracy of charge accumulating on an input of a single transistor multiplier (STM) MAC comprising:
supplying a u(n) signal to at least one charge domain sigma delta converter during a first cycle, wherein the u(n) signal is supplied by a combiner having a notch depth controlled by summing a pulse width modulated (PWM) output into a control gate;
copying an output of the sigma delta converter using a wired device and stored in a CCSR; and
one of adding or removing charge to the summing gate during an output cycle in conformance with digital values stored in the CCSR;

14. A method to control an amount of charge loaded into an MN by setting a notch depth of a notch transfer gate comprising:
providing a two capacitor charge multiplier;
connecting a second floating capacitor of the two capacitor charge multiplier between a barrier lowering gate terminal and a gate over an implant creating the notch; and
loading a charge into the first capacitor of the two capacitor charge multiplier during one cycle; and
setting the notch depth in conformance with a multiplicand applied to the input charge of the two capacitor charge multiplier.

15. The method of claim 14, wherein a controlled charge movement rate is established by operating the set notch depth notch transfer gate over multiple cycles.

16. A circuit to introduce a charge into a charge domain memory node comprising:
a pair of series capacitors, wherein the pair of series capacitors comprises a first capacitor and a second capacitor, the first capacitor having a first terminal and a second terminal coupled to a first terminal of the second capacitor;
a first switch coupled to ground and the first terminal of the first capacitor;
a second current source coupled to the second terminal of the first capacitor and the first terminal of the second capacitor;
a second switch coupled to the second current source, second terminal of the first capacitor and first terminal of second capacitor, and to ground;
a first current source coupled to the first terminal of the first capacitor, the first current source provides a charge input with said second switch closed;
a third current source coupled to the second terminal of the second capacitor;
a third switch coupled to the third current source and to ground;
a common source mosfet having a gate terminal coupled to the second terminal of the first capacitor and the first terminal of the second capacitor and a drain terminal coupled to an active load and the actuator of the second current source and the third current source, the common source mosfet with load providing comparator functionality to actuate the second current source and the third current source with the second switch open and first switch closed when the gate of the mosfet is below a threshold level;
wherein the second capacitor is connected across terminals of a notch transfer gate where the charge on the second capacitor controls a notch height and therefore a multiplicand can provide discrete multiples of a unit charge;
wherein the notch gate is actuated to transfer charge from a source of input charge to a memory node or from a memory node to a second memory node.

17. The circuit of claim 16, wherein the second capacitor controls a depth of a notch of a charge domain structure such that if no charge is removed by the second current source from a node between the first capacitor and the second capacitor then a unit charge is defined after the common source comparator returns to its switch point, and thereafter with a proportional ratio of the second current source and the third current sources a fixed gain from the unit charge can be defined to further adjust the notch depth proportionally to said unit charge.

18. The circuit of claim 16, wherein the first capacitor and the second capacitor are created using one of MIM caps or VIA caps.

19. A sigma delta converter comprising:
a two capacitor charge multiplier wherein the first capacitor first terminal accepts an input charge while a second terminal is grounded during a first cycle;
wherein the first capacitor has a second terminal coupled to an output of a quantizer responsive to the previous cycle filter output for one of add or remove a reference charge to the second terminal of the first capacitor during a second cycle while a switch coupled to its first terminal is grounded;
a comparator coupled to the second terminal of the first capacitor, which is also coupled to the first terminal of the second capacitor, actuates a current source coupled to the second terminal of the second capacitor of said charge multiplier on a third cycle to cancel the charge on the first capacitor and transfers the charge from the first capacitor to a second capacitor of the two capacitor charge multiplier whereafter the switch coupled to the first terminal of the first capacitor is released and the first terminal of the second capacitor is grounded by a switch and a comparator coupled to the second terminal of the second capacitor determines a quantizer output level against a reference which is stored for use during a future second cycle;
and wherein the switch coupled to said first terminal of said second capacitor is released and a second terminal of the second capacitor is shorted to ground by a switch during a fourth cycle and a first current source coupled to the first terminal of said first capacitor returns the charge on the second capacitor to the first capacitor.

20. The common source mosfet element in an STM and two capacitor charge multiplier, wherein the common source mosfet is replaced by a higher gain element, the high gain element being one of a mos controlled thyristor or gate turn off thyristor.

21. A control of charge periods for inputs of an STM, wherein the controls create sinc filter notches optimizing thermal and flicker noise responses.
